(19) United States
(12) Patent Application Publication
(10) Pub. No.: US 2026/0317888 A1
(43) Pub. Date: Oct. 15, 2026

(54) Film Forming Method and Film Forming Apparatus

(71) Applicant: Tokyo Electron Limited, Tokyo (JP)

(72) Inventors: Kazunaga ONO, Yamanashi (JP); Kanto NAKAMURA, Yamanashi (JP); Atsushi SHIMADA, Yamanashi (JP)

(21) Appl. No.: 19/636,574

(22) Filed: Apr. 1, 2026

(30) Foreign Application Priority Data
Apr. 14, 2025 (JP) 2025-066435

(51) Int. Cl. C23C 14/34; C23C 14/08; H01J 37/32; H01J 37/34; H10P 14/60; H10P 14/69

(52) U.S. Cl. CPC C23C 14/34; C23C 14/083; H01J 37/32449; H01J 37/32715; H01J 37/34; H10P 14/6336; H10P 14/6907; H01J 2237/20214; H01J 2237/332

(57) ABSTRACT

A film forming method for forming a thin film containing a metal on a substrate is provided. The method includes introducing an inert gas and a reactive gas containing an element to be incorporated into the thin film into a vacuum processing chamber that accommodates the substrate, cooling the substrate to 150 K or lower, releasing target particles containing the metal toward the substrate from a target containing the metal located in the vacuum processing chamber by plasma generated from gases supplied into the vacuum processing chamber, and forming the thin film by causing the reactive gas and the target particles to react on the cooled substrate.

### CROSS-REFERENCE TO RELATED APPLICATIONS

This application claims priority to Japanese Patent Application No. 2025-066435 filed on Apr. 14, 2025, the entire contents of which are incorporated herein by reference.

### TECHNICAL FIELD

The present disclosure relates to a film forming method and a film forming apparatus.

### BACKGROUND

In manufacturing electronic devices, various types of processing are performed on an object to be processed. Film formation is one of the processing performed on the object to be processed. Sputtering may be used as one of the film formation methods.

Japanese Laid-Open Patent Publication No. 2015-086438 discloses a technique for forming a W (tungsten) film by a sputtering method.

### SUMMARY

The present disclosure provides a technique for improving controllability of reaction in a reactive sputtering method in which a reactive gas is supplied and caused to react with target particles to form a thin film.

A film forming method of the present disclosure is a film forming method for forming a thin film containing a metal on a substrate, the method comprising introducing an inert gas and a reactive gas containing an element to be incorporated into the thin film into a vacuum processing chamber that accommodates the substrate, cooling the substrate to 150 K or lower, releasing target particles containing the metal toward the substrate from a target containing the metal located in the vacuum processing chamber by plasma generated from gases supplied into the vacuum processing chamber, and forming the thin film by causing the reactive gas and the target particles to react on the cooled substrate.

### BRIEF DESCRIPTION OF THE DRAWINGS

FIG. 1 is a longitudinal side view showing a film forming apparatus of an embodiment.

FIG. 2 is a longitudinal side view showing a surface change of a substrate subjected to film formation by the film forming apparatus.

FIG. 3A is a first graph showing test results of Evaluation Test 1.

FIG. 3B is a second graph showing test results of Evaluation Test 1.

FIG. 4A is a third graph showing test results of Evaluation Test 1.

FIG. 4B is a fourth graph showing test results of Evaluation Test 1.

FIG. 5 is a table showing test results of Evaluation Test 2.

FIGS. 6A to 6D are images showing test results of Evaluation Test 2.

FIG. 7 is a first graph showing test results of Evaluation Test 3.

FIG. 8A is a second graph showing test results of Evaluation Test 3.

FIG. 8B is a third graph showing test results of Evaluation Test 3.

### DETAILED DESCRIPTION

### Embodiment

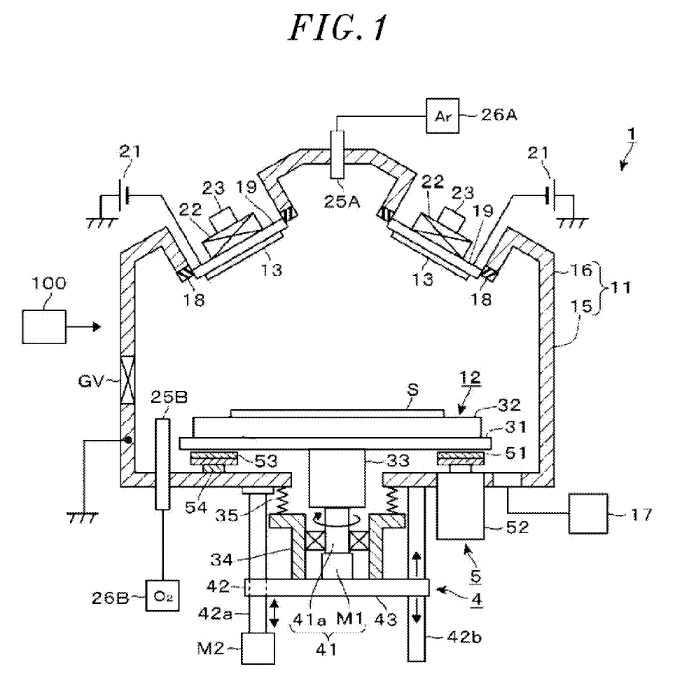

A configuration example of a film forming apparatus according to the present embodiment will be described with reference to FIG. 1. FIG. 1 is a longitudinal side view showing the film forming apparatus of the present disclosure. A film forming apparatus 1 is an apparatus that performs film formation by a reactive sputtering method in which sputtering is performed while supplying a reactive gas to a substrate S, e.g., a semiconductor wafer. Reactive sputtering enables formation of a film containing constituent elements of a reactive gas on the substrate S. The film forming apparatus 1 of the present embodiment includes a cooling mechanism (substrate cooling part) 5, and controls reactivity between the reactive gas and target particles by forming a film while cooling the substrate S to 150 K or lower, preferably 100 K or lower. As a result, the composition ratio of the film after film formation and the progress of the reaction can be controlled within a desired range.

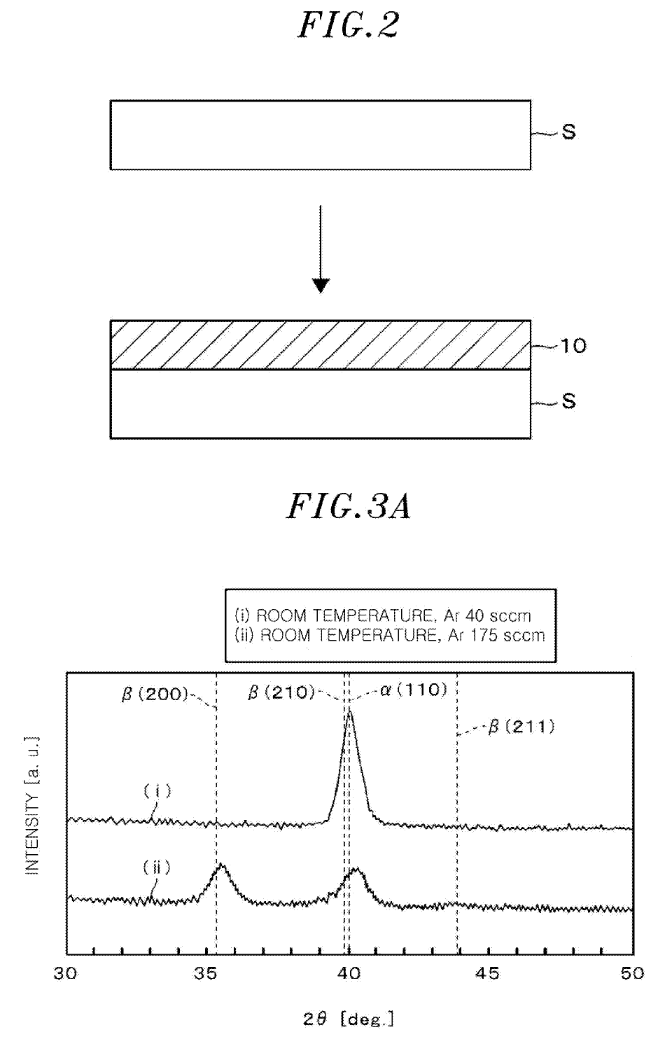

In the present embodiment, an example in which O₂ (oxygen) gas is supplied as a reactive gas and a W (tungsten) film 10 containing O is formed on the substrate S (see FIG. 2) will be described. Specifically, the W film 10 containing O may be, e.g., W₃O (also referred to as “β-tungsten (β-W)”) having a resistivity of about 170 to 200 [μΩ·cm] and a Cr₃Si-type crystal structure. As will be described later using test results, O₂ gas has high reactivity with W, so that the W film 10 containing WO₃ (tungsten trioxide), which is an insulator, tends to be formed in reactive sputtering. The diameter of the substrate S to be processed is, e.g., 300 mm.

By adopting, e.g., the W₃O film, as an underlying film of a wiring layer containing Mo (molybdenum), it is possible to reduce the resistance value of the wiring layer. Further, unlike α-phase (body-centered cubic) W that does not contain oxygen, W₃O that contains a small amount of oxygen and has a β-phase (Cr₃Si-type) crystal structure has a larger effective spin Hall angle compared to the α-phase W. Therefore, W₃O, which is a material having a particularly large effective spin Hall angle among heavy metals having strong spin–orbit interaction, is considered as a channel layer of a magnetoresistive memory, particularly a spin orbit torque (SOT)-type MRAM.

Referring back to the description of FIG. 1, the film forming apparatus 1 includes a processing chamber 11, a placing table 12 that is provided in the processing chamber 11 and places the substrate S thereon, and targets 13 that release a metal (W) toward the substrate S placed on the placing table 12. For example, the processing chamber 11 includes a substantially cylindrical main body 15, and a ceiling portion 16 provided on the main body 15. A gate valve GV is provided on the sidewall of the main body 15. The gate valve GV is opened during transfer of the substrate S, and is closed during film formation.

A through-hole is formed at the center of the bottom portion of the main body 15 in plan view, and a support shaft 33 to be described later is inserted into the through-hole. A cooling mechanism 5 is provided at the bottom portion of the main body 15 to surround the outside of the support shaft 33 inserted into the through-hole. At the bottom portion of the main body 15, a gas supply part 25B and an exhaust port, which will be described later, are formed outside the cooling mechanism 5. A vacuum exhaust part 17 for evacuating the inside of the processing chamber 11 is connected to the exhaust port.

The ceiling portion 16 is located to face the placing table 12, and has an inclined portion whose height position decreases from the center side toward the peripheral side of the placing table 12 when viewed from the placing table 12. In plan view, four through-holes are formed at the inclined portion in the circumferential direction, for example. In each through-hole, a plate-shaped holder 19 supported by an annular insulating member 18 is provided along the edge of the through-hole to close the through-hole. The holder 19 is configured as a cathode connected to a DC power supply 21 to be described later. The targets 13 described above are made of a W metal material having a rectangular plate shape, and are supported to be stacked under the holders 19. In this example, four holders 19 and four targets 13 are provided, but only two of them are illustrated in FIG. 1.

When the holder 19 and the target 13 provided thereunder are set as one pair, four pairs are located at the same height and arranged to have a rotationally symmetric positional relationship around the rotation axis of the substrate S on the placing table 12, which will be described later, in plan view. Each target 13 is located at a position facing the placing table 12, and a main surface (bottom surface) of each target 13 is inclined along the inclined portion of the ceiling portion 16 to face the placing table 12.

Each holder 19 is connected to the negative electrode of the DC power supply 21, and the target 13 is sputtered by a negative DC voltage of, e.g., 30 W to 1500 W, applied from the DC power supply 21. Outside the processing chamber 11, a magnet unit 22 is provided at a position corresponding to the upper surface side of each holder 19. The magnet unit 22 forms magnetic field leaking to the bottom surface side of the target 13. In order to prevent localized erosion of the targets 13 during the sputtering, the magnet unit 22 reciprocates linearly along the upper surface of the holder 19 by a moving mechanism 23.

The film forming apparatus 1 further includes gas supply parts 25A and 25B provided in the processing chamber 11, and gas supply mechanisms 26A and 26B connected to the gas supply parts 25A and 25B via lines and configured to supply various gases. The gas supply mechanisms 26A and 26B supply various gases into the processing chamber 11 via the gas supply parts 25A and 25B. The gas supply part (inert gas supply part) 25A is provided at the central portion of the ceiling portion 16. The gas supply mechanism 26A supplies an inert gas for sputtering (for plasma generation by voltage application from the DC power supply 21). The inert gas is a noble gas selected from a noble gas group consisting of Ne (neon) gas, Ar (argon) gas, Kr (krypton) gas, and Xe (xenon) gas. In this example, argon (Ar) gas is used. As described above, the gas supply part (reactive gas supply part) 25B is provided at the bottom portion of the main body 15. The gas supply mechanism 26B supplies a reactive gas into the processing chamber 11 via the gas supply part 25B.

The gas supply mechanisms 26A and 26B include supply sources of the inert gas and the reactive gas, valves for switching between start and stop of supply of gases into the processing chamber 11, and flow rate controllers such as mass flow controllers for adjusting supply flow rates of gases to the downstream side of channels, respectively. For example, the supply flow rates of the inert gas and the reactive gas can be appropriately set depending on the size and temperature of the substrate S to be subjected to film formation, the size of the processing chamber 11, and the like. In this example, the inert gas is supplied at an appropriate flow rate within a range of 40 sccm to 175 sccm, and O₂ gas is supplied at an appropriate flow rate within a range of 1.5 sccm to 2.5 sccm. Appropriate supply flow rates of the gases can be specified by conducting preliminary tests.

Specifically, in the preliminary tests, conditions suitable for formation of W₃O are specified by changing the supply flow rates of the gases and the flow rate ratios of the respective gases. In a state where the supply of the inert gas and the reactive gas is stopped, the inside of the processing chamber 11 is maintained in a high vacuum atmosphere of, e.g., about 10⁻⁶ Pa (7.5 × 10⁻⁹ Torr). By changing the flow rates of the gases supplied into the processing chamber 11 in this state, the pressure in the processing chamber 11 can be adjusted. Further, by changing the flow rate ratios of the gases, the oxygen content in the W film 10 formed on the substrate S can also be changed. Specifically, by increasing the supply flow rate of the inert gas having a flow rate greater than that of the reactive gas, the pressure in the processing chamber 11 can be adjusted to be higher. As shown in test results to be described later, by adjusting the pressure in the processing chamber 11 to be higher, the film thickness and the in-plane uniformity of the crystal structure of the W film 10 on the substrate S are adjusted. The gas supply parts 25A and 25B and the gas supply mechanisms 26A and 26B are not necessarily provided at different positions as in the example shown in FIG. 1. For example, the gas supply mechanism 26A may be configured to supply the reactive gas as well as the inert gas, and these gases may be supplied from the gas supply part 25A provided at the ceiling portion 16.

The placing table 12 includes a placing table body 31 and an electrostatic chuck 32 provided on the upper surface of the placing table body 31. The electrostatic chuck 32 is configured to fix and hold the substrate S placed on the upper surface thereof by using electrostatic force. The upper end of the support shaft 33 extending in a vertical direction is attached to the center of the bottom surface of the placing table 12, and a moving mechanism 4 is connected to the lower end of the support shaft 33. The moving mechanism 4 includes a rotation part 41 for rotating the support shaft 33 around the central axis, and a linear movement part 42 for vertically moving the support shaft 33 along the central axis. The placing table 12 is rotated around the central axis, and the height position of the placing table 12 is changed by the moving mechanism 4 that rotates and vertically moves the support shaft 33.

The rotation part 41 includes a rotary shaft 41a connected to the lower end of the support shaft 33, and a motor M1 that rotates the rotary shaft 41a. By rotating the rotary shaft 41a connected to the support shaft 33, the placing table 12 is rotated. The motor M1 is, e.g., a direct-drive motor, and a motor M2 to be described later is the same. The linear movement part 42 includes, e.g., the motor M2 that controls rotation, a ball screw 42a rotated by the motor M2, a support plate 43 that is a slider moving in the vertical direction by rotation of the ball screw 42a, and a guide 42b that guides the movement of the support plate 43.

The ball screw 42a and the guide 42b extend in the vertical direction, and are spaced apart from each other in the horizontal direction. The upper ends of the ball screw 42a and the guide 42b are fixed to the peripheral edge of the through-hole formed in the bottom portion of the main body 15. The support plate 43 straddles the ball screw 42a and the guide 42b, and moves up and down by the rotation of the ball screw 42a while being arranged parallel to the bottom portion of the main body 15. The support plate 43 supports, on the upper surface thereof, the motor M1 of the rotation part 41 and a support cylinder 34. The support cylinder 34 is located to surround the rotation part 41, and supports the rotary shaft 41a via bearings. The upper portion of the support cylinder 34 expands in diameter in a flange shape, and a lower end of a cylindrical bellows 35 is connected to the flange-shaped portion. The upper end of the bellows 35 is connected to the peripheral edge of the through-hole formed in the bottom portion of the main body 15. The bellows 35, the support cylinder 34, and the support plate 43 airtightly seal the through-hole formed in the bottom portion of the main body 15.

The moving mechanism 4 configured as described above can raise and lower the placing table 12 between a processing position (see FIG. 1) at which film formation is performed on the substrate S, and a cooling position located below the processing position. The placing table 12 located at the cooling position is cooled by the contact between the bottom surface of the placing table 12 and a cooling head 51 constituting the cooling mechanism 5. During the cooling, the placing table 12 is stopped without being rotated by the rotation part 41. The placing table 12 located at the processing position above the cooling position is separated from the cooling head 51, and thus is not cooled. When the substrate S is placed on the placing table 12 located at the processing position, film formation can be performed while rotating the placing table 12 by the rotation part 41. In this example, the placing table 12 is raised and lowered, but it is also possible to adopt a configuration in which the cooling mechanism 5 is raised and lowered to change the position of the placing table 12 relative to the cooling head 51.

The cooling mechanism 5 includes a refrigerator 52. The refrigerator 52 has a high cooling function. For example, a closed-cycle refrigerator used for a cryopump is adopted. The cooling head 51 described above is located at the top of the refrigerator 52, and a heat transfer part 53 is provided thereon. The heat transfer part 53 is located to face the bottom surface of the placing table 12, and the bottom surface of the heat transfer part 53 is in contact with and joined to the upper surface of the cooling head 51, which is a cooling surface, by an adhesive such as an indium sheet or by bolts, and is cooled by the cooling head 51. The heat transfer part 53 thus cooled cools the placing table 12 by the contact with the bottom surface of the placing table 12 at the cooling position. However, the heat transfer part 53 may be adjacent to the bottom surface of the placing table 12 at the cooling position without being in contact therewith.

The heat transfer part 53 and the cooling head 51 both have a ring shape having the same area and are provided to surround the support shaft 33. The heat transfer part 53 is cooled relatively uniformly and efficiently by the cooling head 51, and is brought into contact with a relatively wide area of the bottom surface of the placing table 12, thereby enhancing in-plane uniformity of cooling and cooling efficiency of the placing table 12. At least one heat-insulating support member 54 that supports the cooling head 51 and the heat transfer part 53 is provided between the bottom surface of the ring-shaped cooling head 51 and the bottom portion of the main body 15. The support member 54 may be made of, e.g., an insulator such as alumina or quartz glass.

The refrigerator 52 has the cooling head 51 at the upper portion of its main body. The main body of the refrigerator 52 cools the cooling head 51 by a Gifford–McMahon cycle (G–M cycle) using a gas such as He. For example, the refrigerator 52 is connected to a compressor (not shown), and includes a piston for adiabatically expanding a high-pressure gas compressed by and sent from the compressor, and performs cooling by expanding the high-pressure gas. The compressor introduces the compressed high-pressure gas into the refrigerator 52 while sucking in a low-pressure gas from the inside of the refrigerator 52 and compressing it again.

The refrigerator 52 configured as described above has cooling capability to cool the substrate S placed on the electrostatic chuck 32 to a temperature within a range of 10 K (−263° C.) to 213 K (−60° C.). The lower limit value of the temperature in this range is a temperature obtained by adding a temperature increase (e.g., 2° C.) at the substrate S to the lower limit cooling temperature (−265° C.) of the refrigerator 52 itself. The refrigerator 52 is not limited to a refrigerator using the G–M cycle, and a Stirling-type system may also be adopted, for example. In the Stirling-type system, a gas filled inside the refrigerator 52 repeatedly undergoes compression and expansion by reciprocating motion of a piston, thereby enabling heat exchange. With this structure, a compact refrigerator can be adopted, but the cooling capability is inferior to that of the G–M cycle refrigerator.

According to the film forming apparatus 1 configured as described above, the linear movement part 42 can set a first state in which the placing table 12 and the cooling mechanism 5 are separated from each other, and a second state in which the placing table 12 and the cooling mechanism 5 are brought close to each other, thereby changing a heat transfer rate from the placing table 12 to the cooling mechanism 5. In the case of cooling the placing table 12, it is required to set the second state in which the placing table 12 and the cooling mechanism 5 are close to each other, so that the heat of the placing table 12 can be transferred to the cooling mechanism 5 and the placing table 12 can be sufficiently cooled. Since the cooling mechanism 5 does not rotate together with the placing table 12, a cooling mechanism having high cooling capability can be adopted. On the other hand, in the case of performing sputtering, by setting the first state in which the placing table 12 and the cooling mechanism 5 are separated, the placing table 12 is physically separated from the cooling mechanism 5 and, thus, the placing table 12 can be freely rotated. According to the processing apparatus described above, sufficient rotation and sufficient cooling of the substrate S placed on the placing table 12 can be achieved, and film formation by sputtering can be performed.

The film forming apparatus 1 includes a controller 100. The controller 100 is configured as a computer including a storage part that stores programs, a memory, and a CPU. The programs are configured such that control signals are output from the controller 100 to individual components of the film forming apparatus 1 in order to perform control for processing the substrate S. The programs are stored in a storage part of the computer, such as a flexible disk, a compact disk, a hard disk, a magneto-optical disk (MO), a nonvolatile memory, or the like, and are read from the storage part and installed in the controller 100. The steps for forming the W film 10 are executed based on the control signals from the controller 100. Specifically, the controller 100 controls the DC power supply 21 for plasma generation that supplies power for plasma generation to the target, the rotation part 41 that rotates the placing table 12, and the linear movement part 42 that moves the placing table 12 between the processing position and the cooling position.

The film formation process performed by the film forming apparatus 1 configured as described above will be described. First, after the inside of the processing chamber 11 is set to a vacuum atmosphere by the vacuum exhaust part 17, the placing table 12 is located at the cooling position by the linear movement part 42 and cooled to the preset temperature described above by the cooling mechanism 5. Next, the gate valve GV is opened, and the substrate S transferred by a substrate transfer device (not shown) is placed on the cooled placing table 12. As a result, the substrate S is cooled to the preset temperature. At the same time, an inert gas for sputtering and a reactive gas are supplied into the processing chamber 11 at preset flow rates by the gas supply parts 25A and 25B (step of introducing an inert gas and a reactive gas, see FIG. 2).

After the placing table 12 is moved to the processing position by the linear movement part 42, the placing table 12 is rotated by the rotation part 41. When the power is supplied from the DC power supply 21 to the holders 19, electric field is generated near the bottom surfaces of the targets 13 held by the holders 19. Due to the electric field thus generated, the inert gas for sputtering supplied from the gas supply part 25A is dissociated to generate ions, and the ions collide with the targets 13, thereby releasing target particles such as W atoms serving as a material of the W film from the targets 13 (step of releasing target particles). Then, by causing W released from the targets 13 to react with the reactive gas and depositing the reaction product on the substrate S, the W film 10 described above is formed on the surface of the substrate S (step of forming a thin film, see FIG. 2).

### Modification

The moving mechanism 4 described above is merely an example, and other structures may be adopted. The structures of the linear movement part 42 and the rotation part 41 are not limited to those described above as long as linear movement and rotational movement can be achieved, and various modifications can be made. The W film 10 is not limited to a film containing W such as a W₃O film, and may be a film containing another metal such as Ti. In that case, film formation is performed using a target containing the metal. Further, although O₂ gas is used as the reactive gas, the reactive gas is not limited thereto, and another reactive gas such as N₂ (nitrogen) gas may also be used.

The substrate S as an object to be processed in the substrate processing apparatus of the present disclosure is not limited to a semiconductor wafer, and may be a flat panel display (FPD) or the like.

It should be noted that the above-described embodiments are illustrative in all respects and are not restrictive. The above-described embodiments may be omitted, replaced, changed or combined in various forms without departing from the scope of the appended claims and the gist thereof.

### Examples

### Evaluation Test 1

Evaluation tests were conducted to verify whether the above-described β-phase W film 10 can be formed by using the film forming method and the film forming apparatus 1 according to the present disclosure. In the following evaluation, in addition to Examples of the present embodiment, evaluation tests were also conducted on Comparative Examples different from Examples of the present embodiment. Six wafers, each having a diameter of 300 mm, were prepared, and a W film was formed on each wafer using the same film forming apparatus 1 under conditions such as film formation time set to achieve a set film thickness of 50 nm. For the W film 10 formed on each substrate S, crystal structure analysis of the W film was performed using X-ray diffraction (XRD).

### A. Test Conditions

### Comparative Example 1

A W film was formed by sputtering on the substrates S at room temperature without performing cooling by the cooling mechanism 5 and without supplying O₂ gas. For different substrates S, the supply conditions for the Ar gas flow rate and the DC power supplied from DC power supply 21 were varied to 40 sccm and 300 W for one substrate, and 175 sccm and 50 W for another substrate.

### Comparative Example 2

A W film was formed by sputtering on the substrates S cooled to 100 K using the cooling mechanism 5 without supplying O₂ gas. The supply flow rate of Ar gas during film formation for each substrate S was the same as that in Comparative Example 1.

### Example 1

A W film was formed by sputtering on the substrates S cooled to 100 K as in Comparative Example 2 under conditions in which the supply flow rate of Ar gas and the supply power were the same as those in Comparative Example 2. O₂ gas was supplied as a reactive gas at a flow rate of 2 sccm to both substrates.

### B. Test Results

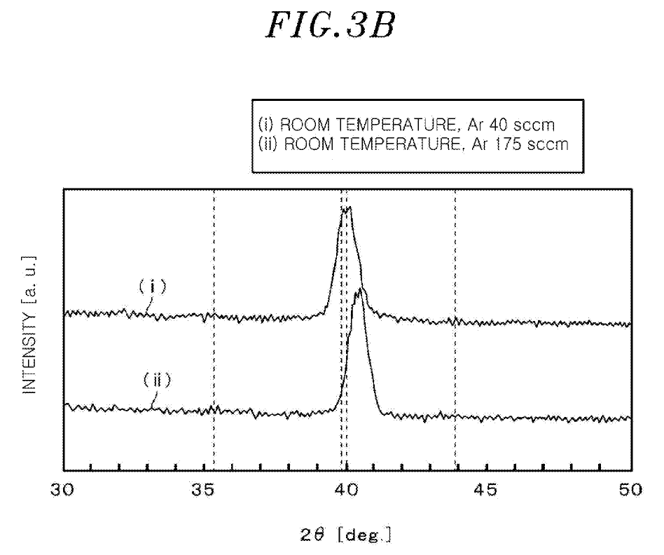

FIGS. 3A and 3B show crystal structure analysis results obtained by X-ray diffraction (XRD) of each W film formed in Comparative Example 1 at room temperature. In FIGS. 3A and 3B, the horizontal axis represents a diffraction angle 2θ, and the vertical axis represents intensity (CPS: counts per second). FIG. 3A shows analysis results of the W film formed at the central portion of the substrate S, and FIG. 3B shows analysis results of the W film formed at the peripheral portion of the substrate S (hereinafter, also referred to as “central/peripheral W films”). In FIGS. 3A and 3B, (i) shows analysis results of the W film formed under the supply condition of Ar gas at 40 sccm, and (ii) shows analysis results of the W film formed under the supply condition of Ar gas at 175 sccm.

### 1. Comparative Example 1

The crystal structure of the W film formed under the supply condition of Ar gas at 40 sccm was a stable body-centered cubic structure at both the central portion and the peripheral portion, and one peak corresponding to the diffraction angle of the oxygen-free α-phase was confirmed (see (i) of FIGS. 3A and 3B). Thus, it was found that under sputtering conditions in which the supply flow rate of Ar gas was 40 sccm and the pressure in the processing chamber 11 was relatively low, oxygen was not incorporated as a constituent element in either the central portion or the peripheral portion of the W film 10.

In the crystal structure of the W film formed under the supply condition of Ar gas at 175 sccm, two peaks corresponding to the diffraction angle of the β-phase, which is a metastable A15-type (Cr₃Si-type) structure, were observed at the central portion (see (ii) of FIG. 3A). At the peripheral portion, only one peak corresponding to the diffraction angle of the α-phase was confirmed (see (ii) of FIG. 3B). The reason for the formation of the β-phase W film under conditions in which O₂ gas was not supplied is considered to be the result of incorporation of oxygen atoms remaining in the processing chamber 11, as constituent elements, into the W film.

Here, in order to form a β-phase W film by a reactive sputtering method, it is necessary to satisfy conditions in which the reaction between target particles released from the target and O (such as O₂ molecules or active O species formed by plasma; hereinafter, may be collectively referred to as “O₂ molecules”) proceeds while enabling the formation of a metastable A15-type structure. For example, even when O₂ molecules and target particles are brought into contact with each other and the reaction proceeds, if the energy contributing to the reaction is small, the deposition of target particles on the substrate S becomes dominant, resulting in the formation of an α-phase W film. In contrast, if the energy contributing to the reaction is excessively large, a more stable WO₃ (insulator) may be formed.

For example, when the pressure in the processing chamber 11 is high, the probability of contact between the target particles and other gas molecules or other target particles along the scattering path from the targets 13 to the substrate S increases. When the target particles are brought into contact with O₂ molecules, the reaction proceeds to form W₃O or WO₃. When the target particles are brought into contact (collide with) Ar atoms, the target particles lose energy due to the collision. Further, when the temperature of the substrate S is high, the reaction may proceed between the W film formed by the deposition of the target particles on the substrate S and O₂ molecules. In order to form a β-phase W film, it is necessary to appropriately control such reaction processes.

The reason for the formation of the β-phase W film at the central portion under the supply condition of Ar gas at 175 sccm and no O₂ gas supply is examined based on the reaction mechanism described above. By increasing the supply flow rate of Ar gas, the pressure in the processing chamber 11 increases. As a result, the target particles lose energy due to the contact with Ar atoms or the like, and it is presumed that the reaction energy obtained when the target particles are brought into contact with O₂ molecules remaining in the processing chamber 11 or the like becomes conditions suitable for the formation of W₃O.

The reason why only the α-phase W film was observed at the peripheral portion is inferred as follows. In other words, as shown in FIG. 1, the targets 13 are located to be inclined relative to the ceiling portion 16. Due to this configuration, the scattering distance of the target particles released from the targets 13 is shorter at the peripheral portion of the substrate S than at the central portion of the substrate S. In regions where the scattering distance of the target particles is short, the frequency of collision with Ar atoms is low, and the energy with which the target particles are incident on the substrate S is relatively high. As a result, the deposition of the target particles alone onto the substrate S proceeds more dominantly than the progress of the reaction between the target particles and O₂ molecules, and an oxygen-free α-phase W film is likely to be formed.

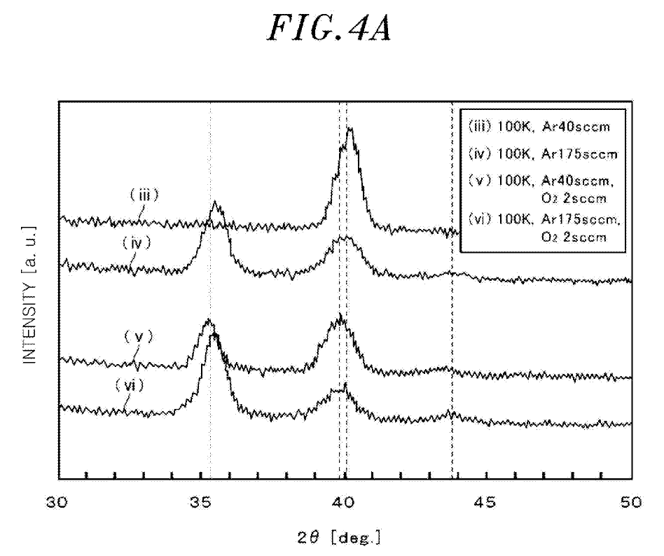

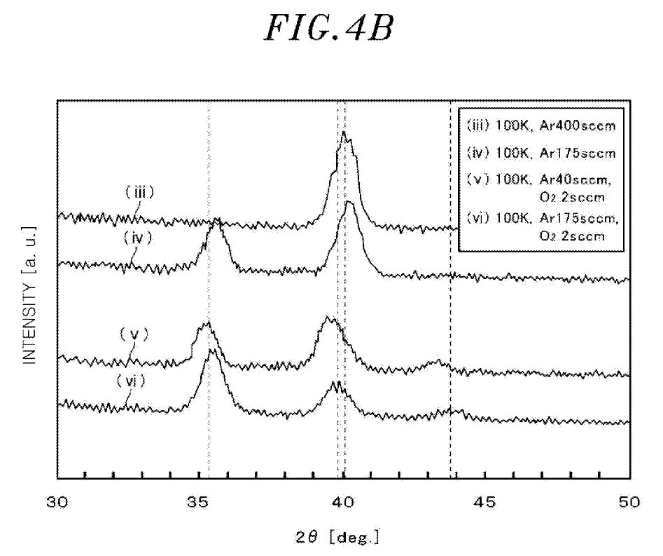

FIGS. 4A and 4B show crystal structure analysis results obtained by XRD for each W film formed in Comparative Example 2 and Example 1, which were formed at a low temperature of 100 K. FIG. 4A shows analysis results for the central portions of the W films, and FIG. 4B shows analysis results for the peripheral portions of the W films. In FIGS. 4A and 4B, (iii) shows the analysis result of the W film formed under the supply condition of Ar gas at 40 sccm in Comparative Example 2, and (iv) shows the analysis result of the W film formed under the supply condition of Ar gas at 175 sccm in Comparative Example 2. Further, (v) shows the analysis result of the W film formed under the supply condition of Ar gas at 40 sccm and O₂ gas at 2 sccm in Example 1, and (vi) shows the analysis result of the W film formed under the supply condition of Ar gas at 175 sccm and O₂ gas at 2 sccm in Example 1.

### 2. Comparative Example 2

In the crystal structure of the W film formed under the supply condition of Ar gas at 40 sccm, one peak corresponding to the diffraction angle of the α-phase was observed at both the central portion and the peripheral portion (see (iii) in FIGS. 4A and 4B). Thus, in the case of forming a W film with a relatively low flow rate of Ar gas, even when the substrate S was cooled to 100 K, a β-phase W film was not formed in either the central portion or the peripheral portion. Similarly to Comparative Example 1, it is considered that the formation of β-phase hardly progresses under low-pressure conditions. Further, when the substrate S is cooled, the reaction between the W film deposited and formed on the substrate S and O₂ molecules becomes less likely to proceed and, thus, the formation of β-phase is also hindered from this perspective.

In the crystal structure of the W film formed under the supply condition of Ar gas at 175 sccm, two peaks corresponding to the diffraction angles of the β phase were observed at both the central portion and the peripheral portion (see (iv) of FIGS. 4A and 4B). However, in the waveform at the peripheral portion shown in (iv) of FIG. 4B, the peak corresponding to the diffraction angle of the α phase is higher than that at the central portion, which suggests that the α phase is also present. This can also be confirmed from the sheet resistance value to be described later (see FIG. 5). According to the comparison with the results of Comparative Example 1, it is presumed that at the peripheral portion of the substrate S in Comparative Example 1, where film formation was performed at room temperature, the deposition of the target particles alone onto the substrate S dominantly proceeded, and thus an oxygen-free α-phase W film was formed, as described above. In contrast, in Comparative Example 2, the cooling of the substrate S reduced the influence of deposition of target particles alone, thereby creating conditions where the reaction between the target particles and O₂ molecules could proceed. However, it is presumed that the reaction with the minute amount of O₂ gas remaining in the processing chamber 11 did not sufficiently proceed, resulting in a mixed state of α phase and β phase.

### 3. Example 1

In the crystal structures of the W films formed under the supply conditions of O₂ gas at 2 sccm and Ar gas at 40 sccm and 175 sccm, two peaks corresponding to the diffraction angles of the β phase were observed at both the central portion and the peripheral portion (see (v) and (vi) of FIGS. 4A and 4B). By forming a W film while supplying a reactive gas at a relatively low flow rate to the substrate S cooled to a low temperature, excessive incorporation of oxygen into the W film at once was suppressed, thereby suppressing the formation of an insulating oxide film (WO₃) and enabling the formation of a β-phase W₃O film having a relatively low oxygen content. Under the conditions where O₂ gas was supplied, the conditions required to form the β-phase were satisfied both at the central portion and the peripheral portion of the cooled substrate S.

### Evaluation Test 2

For the W films formed on the substrates S in Comparative Example 2 and Example 1 of Evaluation Test 1 described above, the distribution of the film thickness and the sheet resistance was measured and evaluated.

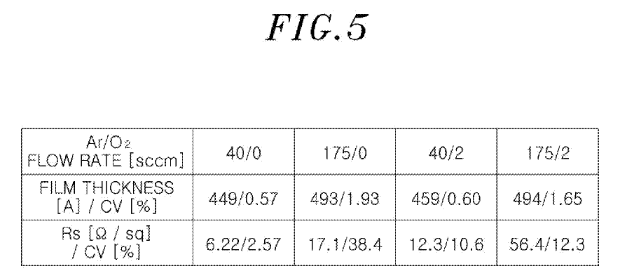

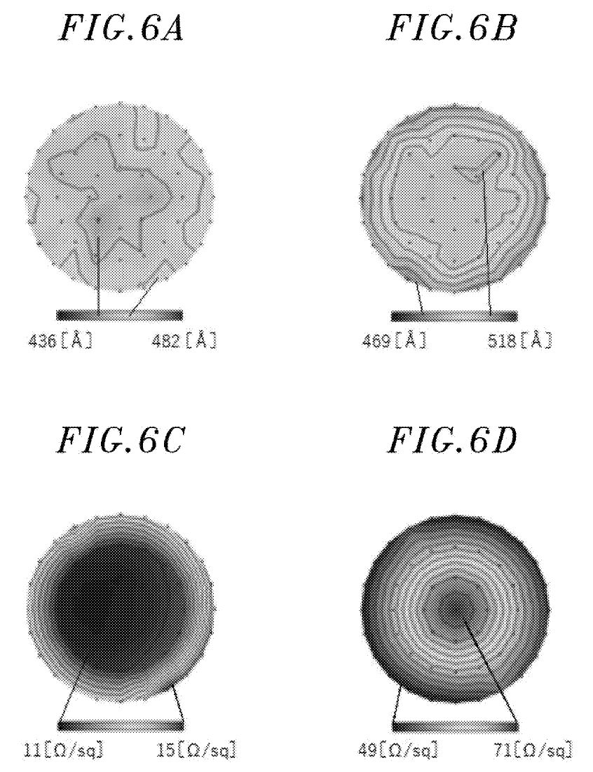

FIG. 5 is a table showing average values and coefficients of variation (CV) of the film thickness and the sheet resistance measured at various in-plane positions for the W films of Comparative Example 2 and Example 1. The CV, which is obtained by dividing the standard deviation of the film thickness and sheet resistance measured at multiple in-plane locations of the W film by the average value, represents the in-plane variation of the film thickness and sheet resistance. A smaller CV indicates smaller variation and better in-plane uniformity. FIGS. 6A and 6B are images showing the distribution of the film thicknesses of the W films formed in Example 1 under the supply conditions of Ar gas at 40 sccm and 175 sccm, respectively, and FIGS. 6C and 6D are images showing the distribution of the sheet resistances of the W films formed in Example 1 under the supply conditions of Ar gas at 40 sccm and 175 sccm, respectively.

As shown in FIG. 5, in the case of the W film formed under the supply condition of Ar gas at 40 sccm in Comparative Example 2, the average film thickness was smallest and the film thickness uniformity was good. Further, the sheet resistance was lowest and the uniformity was highest. Therefore, it was confirmed that a high-purity α-phase W film was formed under the supply condition of Ar gas at 40 sccm in Comparative Example 2. In the case of the W film formed under the supply condition of Ar gas at 175 sccm in Comparative Example 2, it was confirmed that the average film thickness was high and the variation in film thickness was largest. The average sheet resistance was slightly higher than that of the W film formed under the supply condition of Ar gas at 40 sccm in Example 1, and the variation in sheet resistance was largest.

In the case of the W film formed under the supply condition of Ar gas at 40 sccm in Example 1, the average film thickness was slightly small and the film thickness uniformity was good. The sheet resistance was approximately twice the sheet resistance of the W film formed under the supply condition of Ar gas at 40 sccm in Comparative Example 2, which falls within the range of sheet resistance value of the β-phase W film, and the variation in sheet resistance was kept low (see FIGS. 5 and 6). In the case of the W film formed under the supply condition of Ar gas at 175 sccm in Example 1, the average film thickness was high and the variation in film thickness was large. The average sheet resistance increased significantly, but not to the extent that the coexistence of insulating WO₃ was suspected, and remained within the range of sheet resistance value of the β-phase W film. The variation in sheet resistance was slightly higher than that under the supply condition of Ar gas at 40 sccm in Example 1. From the above results, it was confirmed that the high-purity β-phase W film was formed while ensuring high in-plane uniformity in the case of forming the W film under the supply condition of Ar gas at 40 sccm in Example 1.

In the film forming method of the present embodiment, by supplying a small amount of reactive gas and performing reactive sputtering on the cooled substrate S, a β-phase W film can be effectively formed. Further, it was confirmed that a β-phase W film with higher uniformity can be formed by supplying the inert gas at a relatively low flow rate.

### Evaluation Test 3

In the film forming method of the present embodiment, the W films were formed while varying the flow rate of O₂ gas, and the crystal structures of the respective W films were analyzed in the same manner as in Evaluation Test 1. In addition, the deposition rates and resistivities of the W films were measured, and the crystal structure and the like of the W films were examined.

### A. Test Conditions

Six substrates S were prepared, and film formation was performed in a state where the Ar gas flow rate was set to 40 sccm, and the O₂ gas flow rate was set to 0 sccm, 2 sccm, 2.5 sccm, 3 sccm, 4 sccm, and 6 sccm, respectively. Other film formation conditions were the same as those in Example 1.

### B. Test Results

### 1. Crystal Analysis by XRD

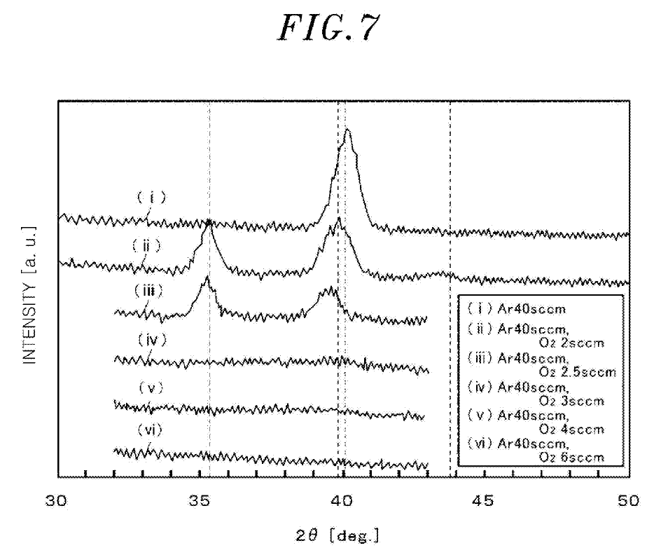

FIG. 7 shows crystal structure analysis results obtained by XRD for the central portions of the W films formed under the above conditions in Evaluation Test 3. As shown in FIG. 7, in the case of the W film formed under the supply condition of O₂ gas at 0 sccm, one peak corresponding to the diffraction angle of the α-phase W film was observed, as in the results of Comparative Example 2 shown in Evaluation Test 1. In the case of the W films formed under the supply condition of O₂ gas at 3 sccm or more, no peak appeared. It is presumed that the reaction with oxygen atoms proceeded, resulting in the formation of an insulating WO₃ film.

In the case of the W films formed under the supply conditions of O₂ gas at 2 sccm and 2.5 sccm, two peaks corresponding to the diffraction angles of the β-phase W film appeared, confirming that the β-phase W film was formed. As described above, according to the film forming method of the present embodiment, by adjusting the flow rate of the reactive gas (O₂ gas in this example), a β-phase W₃O film, which is a metastable substance between the α-phase W film and the insulating WO₃ film, can be formed. However, it was confirmed that the O₂ gas flow rate that allows the formation of the β-phase needs to be within a relatively narrow range such as 2 sccm to 2.5 sccm. It is presumed that when the substrate S is not cooled, the adjustment range becomes even narrower. Thus, the reactive sputtering of the present disclosure, which cools the substrate S to 150 K or lower, may facilitate the adjustment of the progress of the reaction between the target particles and the reactive gas.

### 2. Deposition Rate and Resistivity

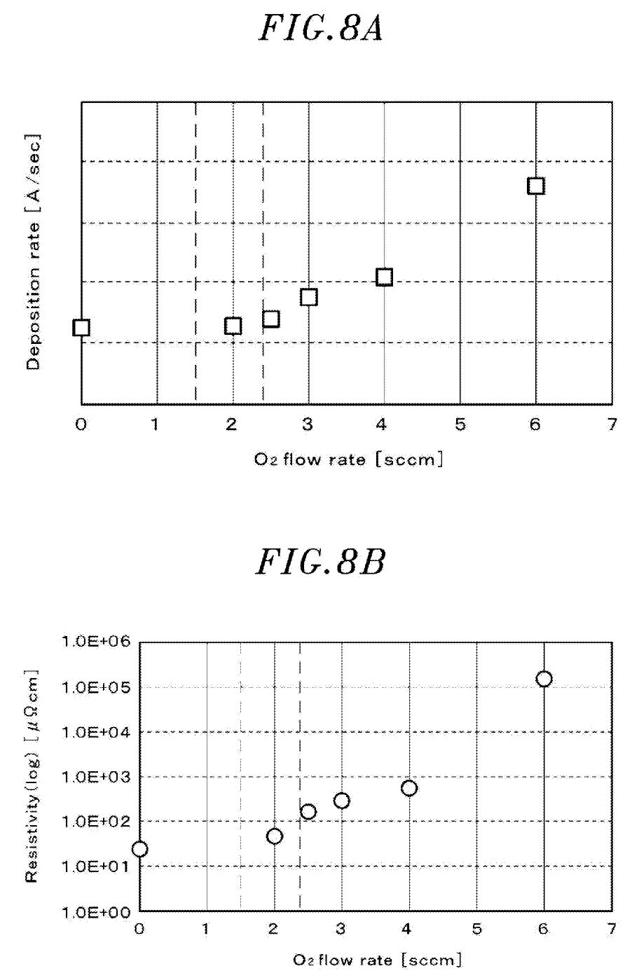

FIG. 8A is a graph showing changes in the deposition rate with respect to the O₂ gas flow rate, and FIG. 8B is a graph showing changes in resistivity with respect to the O₂ gas flow rate on a logarithmic scale. As shown in FIG. 8A, when the O₂ gas flow rate was 2 sccm or less, the deposition rate did not change, and began to increase linearly as the flow rate exceeded 2 sccm. This is considered to be because a greater amount of oxygen atoms was incorporated into the W film and, thus, the film thickness was increased. On the other hand, as shown in FIG. 8B, the resistivity of the W film formed under the supply condition of O₂ gas at 2 sccm was low, similarly to the case of the supply condition of O₂ gas at 0 sccm. As the flow rate of O₂ gas increased from 2 sccm to 4 sccm, the resistivity of the formed W film increased exponentially. Further, the resistivity of the W film formed under the supply condition of O₂ gas at 4 sccm or more increased even more significantly.

According to the film formation results obtained under the supply condition of O₂ gas at 2 sccm, which was confirmed to form the β-phase W film by the crystal structure analysis described above, both the deposition rate and the resistivity were low. On the other hand, when the O₂ gas flow rate was 2.5 sccm, the deposition rate increased slightly, but the resistivity reached 200 μΩ·cm and increased linearly by the increase in the flow rate. This is considered to be because a larger amount of oxygen than that in the β-phase was incorporated, resulting in a state containing WO₃. From the above, the O₂ gas flow rate for forming a β-phase W film is preferably adjusted within the range of 1.5 sccm to 2.5 sccm, and more preferably within the range of 1.5 sccm to 2.3 sccm (see ranges indicated by dashed lines in FIGS. 8A and 8B). As described above, according to the film forming method of the present embodiment, a film having a relatively small reactive gas composition ratio can be uniformly formed by supplying the reactive gas and the inert gas at relatively low flow rates to the cooled substrate S.

1. A film forming method for forming a thin film containing a metal on a substrate, the method comprising:
introducing an inert gas and a reactive gas containing an element to be incorporated into the thin film into a vacuum processing chamber that accommodates the substrate;
cooling the substrate to 150 K or lower;
releasing target particles containing the metal toward the substrate from a target containing the metal located in the vacuum processing chamber by plasma generated from gases supplied into the vacuum processing chamber; and
forming the thin film by causing the reactive gas and the target particles to react on the cooled substrate.

2. The film forming method of claim 1, wherein in said cooling, the substrate is cooled to 100 K or lower.

3. The film forming method of claim 1, wherein the inert gas is at least one noble gas selected from a noble gas group consisting of Ne gas, Ar gas, Kr gas, and Xe gas, and
the reactive gas is at least one of O₂ gas or N₂ gas.

4. The film forming method of claim 1, wherein the metal is W, the reactive gas includes O₂ gas, and
in said forming the thin film, a thin film of W₃O is formed.

5. The film forming method of claim 4, wherein in said forming the thin film, generation of WO₃, which is a byproduct of a reaction between the W and the O₂ gas, is suppressed by cooling the substrate.

6. The film forming method of claim 4, wherein in said introducing, the inert gas is introduced at a flow rate within a range of 40sccm to 175sccm, and the O₂ gas is introduced at a flow rate within a range of 1.5 sccm to 2.5sccm.

7. The film forming method of claim 1, wherein in said forming the thin film, the substrate is rotated about an orthogonal axis passing through a center of the substrate.

8. A film forming apparatus for forming a thin film containing a metal on a substrate, the apparatus comprising:
a vacuum processing chamber having an inner space where a placing table configured to support the substrate is provided;
an inert gas supply part configured to supply an inert gas into the vacuum processing chamber;
a reactive gas supply part configured to supply a reactive gas containing an element to be incorporated into the thin film into the vacuum processing chamber;
a substrate cooling part configured to cool the placing table and to cool the substrate;
a target containing the metal, located in the vacuum processing chamber to face the placing table;
a plasma generating part configured to convert gases supplied into the vacuum processing chamber into plasma; and
a controller,
wherein the controller is configured to output control signals for introducing the inert gas and the reactive gas into the vacuum processing chamber accommodating the substrate, cooling the substrate to 150 K or lower, converting the gases into plasma and releasing target particles containing the metal from the target toward the substrate, and forming the thin film by causing the reactive gas and the target particles to react on the cooled substrate.

9. The film forming apparatus of claim 8, further comprising:
a moving mechanism,
wherein the cooling part is a refrigerator, and includes a main body, a cooling head refrigerated by the main body, and a heat exchange part in contact with the cooling head, and
the moving mechanism changes a distance between the heat exchange part and the placing table, and the placing table is cooled when the placing table is brought close to the heat exchange part.
